(19) United States
(12) Patent Application Publication
(10) Pub. No.: US 2026/0324241 A1
(43) Pub. Date: Oct. 15, 2026

(54) DISPLAY SUBSTRATE, METHOD FOR MANUFACTURING DISPLAY SUBSTRATE, AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Bo SHI, Beijing (CN); Ming HU, Beijing (CN); Gukhwan SONG, Beijing (CN)

(21) Appl. No.: 18/841,506

(22) PCT Filed: Nov. 23, 2023
(86) PCT No.: PCT/CN2023/133584

§ 371 Date: Aug. 26, 2024

(51) Int. Cl. H10K 59/38; H10K 59/12; H10K 59/122; H10K 59/80; H10K 102/00

(52) U.S. Cl. CPC H10K 59/38; H10K 59/1201; H10K 59/122; H10K 59/879; H10K 59/8792; H10K 59/873; H10K 2102/351

(57) ABSTRACT

The present disclosure provides a display substrate, a method for manufacturing a display substrate, and a display apparatus. The display substrate includes a substrate, and a light-emitting layer, an encapsulation layer, a color light-filtering layer, and a light-shielding layer that are located on the substrate. The light-emitting layer includes a plurality of light-emitting structures spaced apart from each other. The encapsulation layer is located on a side of the light-emitting layer away from the substrate. The color light-filtering layer is located on a side of the encapsulation layer away from the substrate; where the color light-filtering layer includes a plurality of color light-filtering portions. The light-shielding layer is provided with a plurality of holes.

### CROSS-REFERENCE TO RELATED APPLICATIONS

The present disclosure is a U.S. national phase of PCT Application No. PCT/CN2023/133584 filed on Nov. 23, 2023 which is hereby incorporated by reference in its entirety.

### TECHNICAL FIELD

The present disclosure relates to a field of display technologies, and in particular, to a display substrate, a method for manufacturing a display substrate, and a display apparatus.

### BACKGROUND

OLEDs (organic light-emitting diodes) have advantages, such as self-illumination, a high efficiency, bright colors, light weight and power saving, a wide use of temperature range, etc., and have been gradually applied to fields, such as large-area display, illumination, vehicle-mounted display, etc.

### SUMMARY

The present disclosure provides a display substrate, a method for manufacturing a display substrate, and a display apparatus.

According to a first aspect of an embodiment of the present disclosure, a display substrate is provided. The display substrate includes: a substrate; a light-emitting layer on the substrate; where the light-emitting layer includes a plurality of light-emitting structures spaced apart from each other; an encapsulation layer on a side of the light-emitting layer away from the substrate; a color light-filtering layer on a side of the encapsulation layer away from the substrate; where the color light-filtering layer includes a plurality of color light-filtering portions, the color light-filtering portions include one or more first color light-filtering portions and one or more non-first color light-filtering portions with color different from a color of each of the first color light-filtering portions, and a thickness of each of the first color light-filtering portions is less than a thickness of each of the non-first color light-filtering portions; and a light-shielding layer provided with a plurality of holes, where an orthogonal projection of one of the holes on the substrate is within an orthogonal projection of one of the color light-filtering portions on the substrate; the light-shielding layer is located on a side of the first color light-filtering portions away from the substrate, and a surface of the light-shielding layer facing the substrate is substantially flush.

In an embodiment, the display substrate further includes: a defining layer on the side of the encapsulation layer away from the substrate; where the defining layer is provided with a plurality of openings; each of the color light-filtering portions is at least partially located in one of the openings; for each of the first color light-filtering portions, the first color light-filtering portion is entirely located within one of the openings, and a surface of the first color light-filtering portion away from the substrate is flush with a surface of the defining layer away from the substrate; a part of the surface of the light-shielding layer facing the substrate is in contact with the first color light-filtering portions, and the other part of the surface of the light-shielding layer facing the substrate is in contact with the defining layer; and for each of the non-first color light-filtering portions, a part of the non-first color light-filtering portion is located on a side of the light-shielding layer away from the substrate.

In an embodiment, for one of the openings in which one of the first color light-filtering portions is located, the opening includes a first opening portion and a second opening portion on a side of the first opening portion away from the substrate; the second opening portion includes a bottom surface outside the first opening portion and connected to a side surface of the first opening portion, and a side surface formed by extending outward from an outer edge of the bottom surface in a direction away from the substrate.

In an embodiment, the display substrate further includes: a defining layer on the side of the encapsulation layer away from the substrate; where the defining layer is provided with a plurality of openings; each color light-filtering portion among the color light-filtering portions is at least partially located in one of the openings; and a plurality of padding portions between the first color light-filtering portions and the encapsulation layer; where for each of the openings in which each of the first color light-filtering portions is located, an orthogonal projection of the opening on the substrate is within an orthogonal projection of one of the padding portions on the substrate; a surface of each of the first color light-filtering portions away from the substrate is flush with a surface of each of the non-first color light-filtering portions away from the substrate; the surface of the light-shielding layer facing the substrate is entirely in contact with the color light-filtering layer.

In an embodiment, a refractive index of each of the padding portions is less than or equal to a refractive index of the color light-filtering layer.

In an embodiment, the padding portions and the defining layer are formed as an integrated structure.

In an embodiment, the padding portions and the defining layer are separate structures.

In an embodiment, an orthogonal projection of each of the padding portions on the substrate is within an orthogonal projection of one of the first color light-filtering portions on the substrate.

In an embodiment, an edge of the orthogonal projection of each of the padding portions on the substrate is flush with an edge of the orthogonal projection of one of the first color light-filtering portions on the substrate.

In an embodiment, the display substrate further includes: a defining layer on the side of the encapsulation layer away from the substrate; where the defining layer is provided with a plurality of openings; each of the color light-filtering portions is at least partially located in one of the openings; a surface of the defining layer away from the substrate is entirely covered by the first color light-filtering portions; for each of the first color light-filtering portions, a portion of the first color light-filtering portion on a side of the defining layer away from the substrate is covered by the non-first color light-filtering portions; and the surface of the light-shielding layer facing the substrate is entirely in contact with the non-first color light-filtering portions.

In an embodiment, the non-first color light-filtering portions include one or more second color light-filtering portions and one or more third color light-filtering portions; wherein, for each of the first color light-filtering portions, a portion of the first color light-filtering portion on the side of the defining layer away from the substrate is entirely covered by the second color light-filtering portions; or, the portion of the first color light-filtering portion, on the side of the defining layer away from the substrate is entirely covered by the third color light-filtering portions; or, for in the portion of the first color light-filtering portions, on the side of the defining layer away from the substrate, a part of the portion is covered by the second color light-filtering portions, and the other part of the portion is covered by the third color light-filtering portions.

In an embodiment, the second color light-filtering portions are connected as an integrated structure, or the third color light-filtering portions are connected as an integrated structure.

In an embodiment, the first color light-filtering portions are connected as an integrated structure.

In an embodiment, a refractive index of each of the color light-filtering portions is larger than a refractive index of the defining layer.

In an embodiment, the display substrate further includes: a planarization layer between the light-shielding layer and the color light-filtering layer; where the planarization layer at least covers the first color light-filtering portions.

In an embodiment, an orthogonal projection of the planarization layer on the substrate covers an orthogonal projection of the color light-filtering layer on the substrate, and the surface of the light-shielding layer facing the substrate is entirely in contact with the planarization layer.

In an embodiment, the planarization layer covers the first color light-filtering portions, a surface of the planarization layer away from the substrate is flush with a surface of each of the non-first color light-filtering portions away from the substrate, and a part of the surface of the light-shielding layer facing the substrate is in contact with the planarization layer, and other part of the surface is in contact with the non-first color light-filtering portions.

According to a second aspect of an embodiment of the present disclosure, a method for manufacturing a display substrate is provided. The method for manufacturing a display substrate includes: providing a substrate; forming a light-emitting layer on the substrate; where the light-emitting layer includes a plurality of light-emitting structures spaced apart from each other; forming an encapsulation layer on a side of the light-emitting layer away from the substrate; forming a color light-filtering layer on a side of the encapsulation layer away from the substrate; where the color light-filtering layer includes a plurality of color light-filtering portions; the color light-filtering portions include one or more first color light-filtering portions and one or more non-first color light-filtering portions with color different from a color of each of the first color light-filtering portions; a thickness of each of the first color light-filtering portions is less than a thickness of each of the non-first color light-filtering portions; and a distance from a surface of each of the first color light-filtering portions away from the substrate to the substrate is less than a distance from a surface of each of the non-first color light-filtering portions away from the substrate to the substrate; forming a light-shielding film layer on a side of the color light-filtering layer away from the substrate; where an orthogonal projection of the light-shielding film layer on the substrate covers the substrate, and a thickness of the light-shielding film layer is greater than a height difference between the surface of each of the non-first color light-filtering portions away from the substrate and the surface of each of the first color light-filtering portions away from the substrate; and obtaining a light-shielding layer by patterning the light-shielding film layer to form a plurality of holes; where an orthogonal projection of one of the holes on the substrate is within an orthogonal projection of one of the color light-filtering portions on the substrate.

In an embodiment, the thickness of the light-shielding film layer is greater than a maximum thickness of the light-shielding layer.

According to a third aspect of an embodiment of the present disclosure, a display apparatus is provided. The display apparatus includes the above display substrate.

According to the display substrate, the method for manufacturing a display substrate, and the display apparatus provided by the embodiments of the present disclosure, because the surface of the light-shielding layer of the display substrate facing the substrate is substantially flush, the problem, that different thickness of the color light-filtering portions with different colors result in a difference-in-level in the surface of the light-shielding layer facing the substrate such that the light-shielding layer is broken or the light-shielding layer is separated from the adjacent film layer, may be avoided, which may improves a yield of the display substrate; the light-shielding layer is arranged on the side of the first color light-filtering portion away from the substrate, which helps to improve a dark state effect of the display substrate in a non-display state; and the color light-filtering layer is arranged on the side of the encapsulation layer away from the substrate, such that the color light-filtering layer may filter incident external environment light, which reduces the reflection amount of the incident environment light, and may reduce loss of exited light and improve a light exiting efficiency compared with a polarizer.

### BRIEF DESCRIPTION OF DRAWINGS

FIG. 1 is a partial cross-sectional view of a display substrate provided by an exemplary embodiment of the present disclosure.

FIG. 2 is a partial cross-sectional view of a display substrate provided by another exemplary embodiment of the present disclosure.

FIG. 3 is a partial cross-sectional view of a display substrate provided by still another exemplary embodiment of the present disclosure.

FIG. 4 is a partial cross-sectional view of a display substrate provided by yet another exemplary embodiment of the present disclosure.

FIG. 5 is a partial cross-sectional view of a display substrate provided by yet another exemplary embodiment of the present disclosure.

FIG. 6 is a partial cross-sectional view of a display substrate provided by yet another exemplary embodiment of the present disclosure.

FIG. 7 is a schematic structural diagram of a first color light-filtering portion of a display substrate provided by an exemplary embodiment of the present disclosure.

FIG. 8 is a schematic structural diagram of a second color light-filtering portion of a display substrate provided by an exemplary embodiment of the present disclosure.

FIG. 9 is a schematic structural diagram of a third color light-filtering portion of a display substrate provided by an exemplary embodiment of the present disclosure.

FIG. 10 is a partial cross-sectional view of a display substrate provided by yet another exemplary embodiment of the present disclosure.

FIG. 11 is a partial cross-sectional view of a display substrate provided by yet another exemplary embodiment of the present disclosure.

FIG. 12 is a partial cross-sectional view of a first intermediate structure of a display substrate provided by an exemplary embodiment of the present disclosure.

FIG. 13 is a partial cross-sectional view of a second intermediate structure of a display substrate provided by an exemplary embodiment of the present disclosure.

FIG. 14 is a partial cross-sectional view of a third intermediate structure of a display substrate provided by an exemplary embodiment of the present disclosure.

FIG. 15 is a partial cross-sectional view of a fourth intermediate structure of a display substrate provided by an exemplary embodiment of the present disclosure.

FIG. 16 is a partial cross-sectional view of a display substrate provided by yet another exemplary embodiment of the present disclosure.

### DETAILED DESCRIPTION

Exemplary embodiments will be described in detail herein, with examples thereof represented in the accompanying drawings. When the following description involves the accompanying drawings, same numerals in different figures represent same or similar elements unless otherwise indicated. Embodiments described in the following exemplary embodiments do not represent all embodiments consistent with the present disclosure. On the contrary, they are only examples of apparatuses and methods that are consistent with some aspects of the present disclosure as detailed in the appended claims.

Terms used in the present disclosure are only for a purpose of describing specific embodiments, and are not intended to limit the present disclosure. Singular forms, “a/an,” “the,” and “this,” used in the present disclosure and the appended claims are also intended to include majority forms, unless the context clearly indicates other meanings. It should also be understood that the term “and/or” used herein refers to and includes any or all possible combinations of one or more related listed items.

It should be understood that although terms, such as “first,” “second,” “third,” etc., may be used in the present disclosure to describe various information, such information should not be limited by these terms. These terms are only used to distinguish a same type of information from each other. For example, without departing from the scope of the present disclosure, first information may also be referred to as second information, and similarly, the second information may also be referred to as the first information. Depending on the context, the term “if” used herein may be interpreted as “when,” “while,” or “in response to determining.”

Embodiments of the present disclosure provide a display substrate and a display apparatus. The display substrate and the display apparatus in the embodiments of the present disclosure will be described in detail below with reference to the accompanying drawings. Features in the embodiments described below may complement or be combined with each other without conflict.

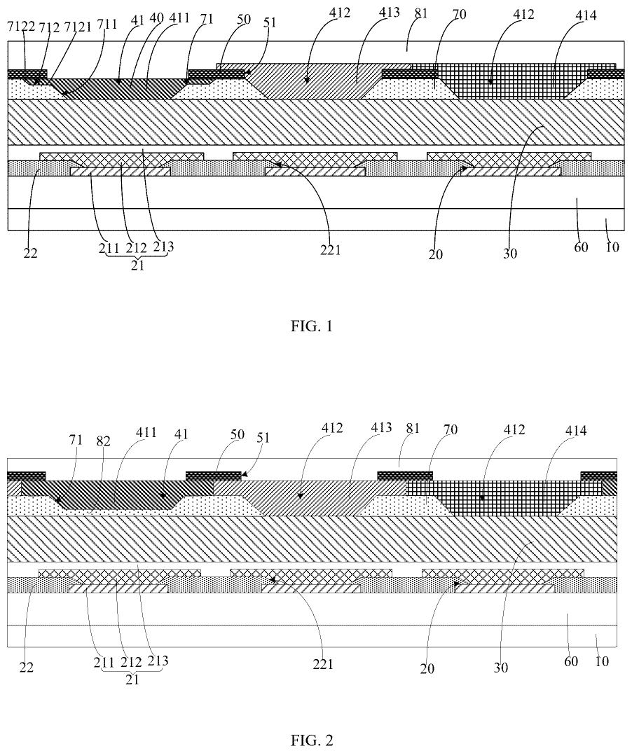

An embodiment of the present disclosure provides a display substrate. As shown in FIG. 1, the display substrate includes a substrate 10, and a light-emitting layer 20, an encapsulation layer 30, a color light-filtering layer 40, and a light-shielding layer 50 that are located on (or above) the substrate 10.

The light-emitting layer 20 includes a plurality of light-emitting structures 21 spaced apart from each other. The encapsulation layer 30 is located on a side of the light-emitting layer 20 away from the substrate 10. The color light-filtering layer 40 is located on a side of the encapsulation layer 30 away from the substrate 10. The color light-filtering layer 40 includes a plurality of color light-filtering portions 41, the color light-filtering portions 41 include one or more first color light-filtering portions 411 and one or more non-first color light-filtering portions 412 with color different from a color of the first color light-filtering portion 411. A thickness of the first color light-filtering portion 411 is less than a thickness of the non-first color light-filtering portion 412. The light-shielding layer 50 is provided with a plurality of holes 51, and an orthogonal projection of one of the holes 51 on the substrate is within an orthogonal projection of one of the color light-filtering portions 41 on the substrate 10. The light-shielding layer 50 is located on a side of the first color light-filtering portion 411 away from the substrate 10, and a surface of the light-shielding layer 50 facing the substrate 10 is substantially flush. The surface of the light-shielding layer 50 facing the substrate 10 being substantially flush means that the surface of the light-shielding layer 50 facing the substrate 10 is flush everywhere, or differences between distances from different regions of the surface of the light-shielding layer 50 facing the substrate 10 to the substrate 10 are small.

According to the display substrate provided by the embodiment of the present disclosure, because the surface of the light-shielding layer facing the substrate is substantially flush, the problem, that different thickness of the color light-filtering portions with different colors result in a difference-in-level in the surface of the light-shielding layer facing the substrate such that the light-shielding layer is broken or the light-shielding layer is separated from the adjacent film layer, may be avoided, which may improves a yield of the display substrate; the light-shielding layer is arranged on the side of the first color light-filtering portion away from the substrate, which helps to improve a dark state effect of the display substrate in a non-display state; and the color light-filtering layer is arranged on the side of the encapsulation layer away from the substrate, such that the color light-filtering layer may filter incident external environment light, which reduces the reflection amount of the incident environment light, and may reduce loss of exited light and improve a light exiting efficiency compared with a polarizer.

In an embodiment, the substrate 10 may be a flexible substrate or a rigid substrate. The material of the flexible substrate may include one or more of polyethylene terephthalate, polycarbonate, and an organic resin material. The organic resin material may include epoxy resin, triazine, silicone resin, polyimide, etc. The rigid substrate includes any one of for example a glass substrate, a quartz substrate, a sapphire substrate, etc.

In an embodiment, as shown in FIG. 1, the display substrate further includes a driving circuit layer 60 between the substrate 10 and the light-emitting layer 20. The driving circuit layer 60 includes a plurality of pixel circuits for driving the light-emitting structures 21. The pixel circuits may correspond to the light-emitting structures 21 one-to-one, and each of the pixel circuits is for driving a corresponding light-emitting structure 21. Each of the pixel circuits may include a thin film transistor and a capacitor.

In an embodiment, the light-emitting layer 20 includes light-emitting structures 21 emitting at least three different colors of light. For example, the light-emitting layer 20 may include a light-emitting structure emitting red light, a light-emitting structure emitting green light, and a light-emitting structure emitting blue light.

In an embodiment, as shown in FIG. 1, each of the light-emitting structures 21 includes a first electrode 211, a light-emitting material layer 212 on a side of the first electrode 211 away from the substrate 10, and a second electrode 213 on a side of the light-emitting material layer 212 away from the substrate 10. One of the first electrode 211 and the second electrode 213 is an anode, and the other of the first electrode 211 and the second electrode 213 is a cathode. The cathode may be a common electrode, and cathodes of all of the light-emitting structures 21 are connected to each other to form a planar electrode. In some embodiments, the light-emitting material layer 212 is an organic light-emitting material layer, and the light-emitting structure 21 is an OLED.

In an embodiment, as shown in FIG. 1, the light-emitting layer 20 further includes a pixel definition layer 22, and the pixel definition layer is provided with a plurality of pixel openings 221. The pixel definition layer 22 is located on a side of the first electrode 211 away from the substrate 10, and one pixel opening 221 exposes at least a part of a corresponding first electrode 211. The light-emitting material layer 212 of each of the light-emitting structures 21 is at least partially located in the pixel opening 221. The second electrode 213 is at least partially located on a side of the pixel definition layer 22 away from the substrate 10.

In an embodiment, the encapsulation layer 30 is a thin film encapsulation layer, the thin film encapsulation layer includes one or more organic layers and one or more inorganic layers alternately arranged, and a film layer with a maximum distance from the substrate 10 is an inorganic layer. For example, the thin film encapsulation layer may include two inorganic layers and an organic layer between the two inorganic layers.

In an embodiment, as shown in FIG. 1, the display substrate further includes a defining layer 70 on a side of the encapsulation layer 30 away from the substrate 10, the defining layer 70 is provided with a plurality of openings 71, and the defining layer 70 is for defining each of the color light-filtering portions 41. The color light-filtering portion 41 is at least partially located within the opening 71. The color light-filtering portions 41 may correspond to the openings 71 one-to-one, and each of the color light-filtering portions 41 is at least partially located within a corresponding opening 71.

Further, a refractive index of the defining layer 70 is less than a refractive index of the color light-filtering portion 41. By this setting, after the light emitted by the light-emitting structure 21 enters the defining layer 70 from the color light-filtering portion 41, most of the light is reflected and exits through the hole of the light-shielding layer 50, which helps to reduce the loss of the light and improve the light exiting efficiency of the display substrate.

Further, the difference between the refractive index of the color light-filtering portion 41 and the refractive index of the defining layer 70 ranges from 0.1 to 0.2.

In an embodiment, as shown in FIG. 1, the display substrate further includes a protection layer 81 on a side of the color light-filtering layer 40 away from the substrate 10. An orthogonal projection of the protection layer 81 on the substrate 10 covers an orthogonal projection of the color light-filtering layer 40 on the substrate 10, and covers an orthogonal projection of the light-shielding layer 50 on the substrate 10. The material of the protection layer 81 may be an organic resin.

In an embodiment, the color light-filtering layer 40 includes color light-filtering portions 41 with at least three colors, the color light-filtering portions 41 correspond to the light-emitting structures 21 one-to-one, an orthogonal projection of each of the color light-filtering portions 41 on the substrate 10 covers an orthogonal projection of a pixel opening 221 for the corresponding light-emitting structure 21 on the substrate 10, and a color of the color light-filtering portion 41 is the same as a color of the light emitted by the corresponding light-emitting structure 21. By this setting, an amount of the light, emitted by the light-emitting structure 21, entering the corresponding color light-filtering portion 41 is large, which helps to improve a utilization rate of the light.

The orthogonal projection of the color light-filtering portion 41 on the substrate 10 covering the orthogonal projection of the pixel opening 221 for the light-emitting structure 21 on the substrate 10 means that an area of the orthogonal projection of the color light-filtering portion 41 on the substrate 10 is greater than an area of the orthogonal projection of the corresponding pixel opening 221 on the substrate 10, or the orthogonal projection of the color light-filtering portion 41 on the substrate 10 substantially coincides with the orthogonal projection of the corresponding pixel opening 221 on the substrate 10. Preferably, the area of the orthogonal projection of the color light-filtering portion 41 on the substrate 10 is larger than the area of the orthogonal projection of the corresponding pixel opening 221 on the substrate 10, so that more of the light emitted by the light-emitting structure 21 may enter the corresponding color light-filtering portion 41.

In an embodiment, as shown in FIG. 1, the non-first color light-filtering portions 412 include one or more second color light-filtering portions 413 and one or more third color light-filtering portions 414. The first color light-filtering portion 411 is a red light-filtering portion, the second color light-filtering portion 413 is a green light-filtering portion, and the third color light-filtering portion 414 is a blue light-filtering portion. That is, the thickness of the red light-filtering portion 411 is less than the thickness of the green light-filtering portion and less than the thickness of the blue light-filtering portion. Relationships between thicknesses of the color light-filtering portions with different colors may ensure a white balance effect of the display substrate. In some embodiments, a thickness of the green light-filtering portion may be the same as a thickness of the blue light-filtering portion.

In an embodiment, as shown in FIG. 1, the first color light-filtering portion 411 is entirely located within the opening 71, and a surface of the first color light-filtering portion 411 away from the substrate 10 is flush with a surface of the defining layer 70 away from the substrate 10. A part of the surface of the light-shielding layer 50 facing the substrate 10 is in contact with the first color light-filtering portion 411, and the other part of the surface of the light-shielding layer 50 facing the substrate 10 is in contact with the defining layer 70. A part of the non-first color light-filtering portion 412 is located on the side of the light-shielding layer 50 away from the substrate 10. By setting the surface of the first color light-filtering portion 411 away from the substrate 10 to be flush with the surface of the defining layer 70 away from the substrate 10, when the light-shielding layer 50 is formed on the surfaces of the first color light-filtering portion 411 and the defining layer 70 away from the substrate, the problems of breakage of the light-shielding layer 50 and separation of the light-shielding layer 50 from the first color light-filtering portion 411 and the defining layer 70 may be avoided. In the embodiment shown in FIG. 1, adjacent first color light-filtering portions 411 are spaced apart from each other, adjacent second color light-filtering portions 413 are spaced apart from each other, and adjacent third color light-filtering portions 414 are spaced apart from each other.

Further, as shown in FIG. 1, an opening 71 in which the first color light-filtering portion 411 is located includes a first opening portion 711 and a second opening portion 712 on a side of the first opening portion 711 away from the substrate 10. The second opening portion 712 includes a bottom surface 7121 outside the first opening portion 711 and connected to a side surface of the first opening portion 711, and a side surface 7122 formed by extending outward from an outer edge of the bottom surface 7121 in a direction away from the substrate 10. By setting the opening in which the first color light-filtering portion 411 is located to include the first opening portion 711 and the second opening portion 712, and by setting the second opening portion 712 to include the bottom surface 7121 connected to the side of the first opening portion 711, when forming the first color light-filtering portion 411, the second opening portion 712 may have an effect for buffering the material of the first color light-filtering portion 411, to prevent the material of the first color light-filtering portion 411 from overflowing the opening 71, and ensure that the surface of the formed first color light-filtering portion 411 away from the substrate 10 is substantially flush with the surface of the defining layer 70 away from the substrate 10.

Further, a depth of the first opening portion 711 is about 2 μm, and a depth of the second opening portion 712 is about 1 μm.

In an embodiment, the opening 71 of the defining layer 70 may be formed by an exposure and development process, and in the exposure and development process, the amount of the light entering different regions of the defining layer 70 may be controlled by a halftone mask plate, so that a shape of the opening 71 for the first color light-filtering portion 411 is different from shapes of the openings 71 for the non-first color light-filtering portions 412.

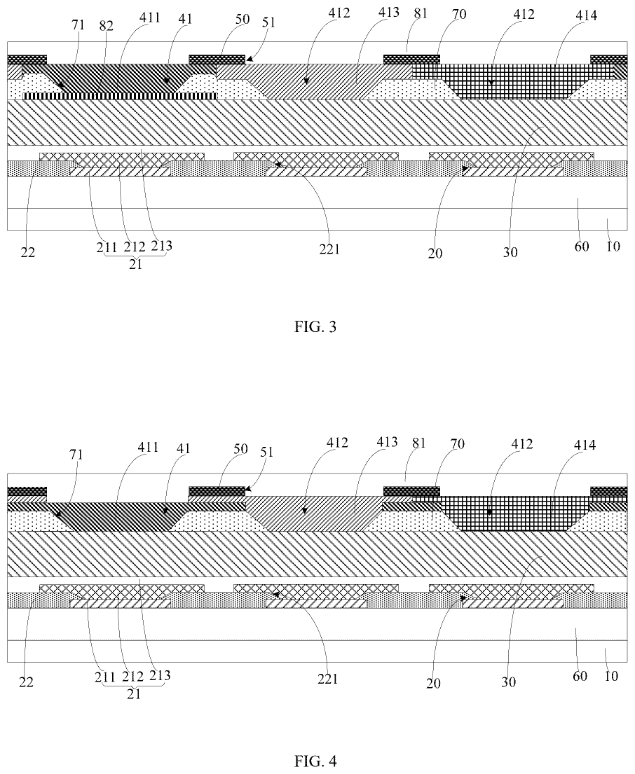

In an embodiment, as shown in FIG. 2 and FIG. 3, the display substrate further includes a plurality of padding portions 82. The padding portions 82 are located between the first color light-filtering portions 411 and the encapsulation layer 30. An orthogonal projection of a bottom surface of the opening 71 in which each of the first color light-filtering portions 411 is located on the substrate 10 is within an orthogonal projection of one of the padding portions 82 on the substrate 10. A surface of the first color light-filtering portion 411 away from the substrate 10 is flush with a surface of the non-first color light-filtering portion 412 away from the substrate 10. A surface of the light-shielding layer 50 facing the substrate 10 is entirely in contact with the color light-filtering layer 40. Specifically, a part of the surface of the light-shielding layer 50 facing the substrate 10 is in contact with the first color light-filtering portion 411, and the other part of the surface is in contact with the non-first color light-filtering portion 412. The padding portions 82 may correspond to the first color light-filtering portions 411 one-to-one, and an orthogonal projection, of a bottom surface of the opening 71 in which each of the first color light-filtering portions 411 is located, on the substrate 10 is within an orthogonal projection of the corresponding padding portion 82 on the substrate 10. By setting the padding portion 82, a distance from the surface of the first color light-filtering portion 411 away from the substrate 10 to the substrate 10 may be increased, so that the surface of the first color light-filtering portion 411 away from the substrate 10 may be substantially flush with the surface of the non-first color light-filtering portion 412 away from the substrate 10, that is, the surface of the color light-filtering layer 40 away from the substrate 10 is substantially flush everywhere. Therefore, the surface of the light-shielding layer 50 formed on the color light-filtering layer 40 facing the substrate is substantially flush, which may avoid the problems of the breakage of the light-shielding layer 50 and separation of the light-shielding layer 50 from the first color light-filtering portion 411 and the defining layer 70. The light-shielding layer 50 is entirely located on the side of the color light-filtering layer 40 away from the substrate 10, which may further improve the dark state effect of the display substrate in the non-display state. A thickness of the padding portion 82 may be equal to a difference between the thickness of the non-first color light-filtering portion 412 and the thickness of the first color light-filtering portion 411.

Further, a refractive index of the padding portion 82 is less than or equal to a refractive index of the color light-filtering layer 40. By this setting, when the light emitted by the light-emitting structure 21 enters the color light-filtering layer 40 through the padding portion 82, the amount of the reflected light may be reduced, and the light exiting efficiency of the display substrate may be improved.

In an embodiment, as shown in FIG. 2, the padding portion 82 and the defining layer 70 are formed as an integrated structure. By this setting, the padding portion 82 and the defining layer 70 may be formed simultaneously, which helps to simplify the process of manufacturing the display substrate. Specifically, when the openings 71 of the defining layer 70 are formed by the exposure and development process, the amount of the light entering different regions of the defining layer 70 may be controlled by the halftone mask plate, to form the openings 71 with different depths.

In another embodiment, as shown in FIG. 3, the padding portion 82 and the defining layer 70 are separate structures. The padding portion 82 is formed before forming the defining layer 70, to facilitate control of the thickness of the padding portion 82. The material of the padding portion 82 may be the same as or different from the material of the defining layer 70.

Further, an orthogonal projection of the padding portion 82 on the substrate 10 is within an orthogonal projection of the first color light-filtering portion 411 on the substrate 10. By this setting, the surface of the non-first color light-filtering portion 412 away from the substrate 10 being raised due to the extension of the padding portion 82 to the bottom of the non-first color light-filtering portion 412 may be avoided.

Further, an edge of the orthogonal projection of the padding portion 82 on the substrate 10 is flush with an edge of the orthogonal projection of the first color light-filtering portion 411 on the substrate 10. This setting may ensure that each of regions of the surface of the first color light-filtering portion 411 away from the substrate 10 is raised by the raising portion 82, so that the surface of the first color light-filtering portion 411 away from the substrate is substantially flush with the surface of the non-first color light-filtering portion 412 away from the substrate, and may avoid the problem that the surface of the non-first color light-filtering portion 412 away from the substrate 10 being raised is not conducive to that the surface of the color light-filtering layer 40 away from the substrate 10 is flush everywhere.

In an embodiment, as shown in FIG. 4 to FIG. 6, the surface of the defining layer 70 away from the substrate 10 is entirely covered by the first color light-filtering portions 411; the non-first color light-filtering portion(s) 412 covers/cover a portion, of the first color light-filtering portion 411, on a side of the defining layer 70 away from the substrate 10; and the surface of the light-shielding layer 50 facing the substrate 10 is entirely in contact with the non-first color light-filtering portion 412. By this setting, the surface, of the portion of the first color light-filtering portion 411 covering the defining layer 70, away from the substrate 10 is flush, then the surface, of the portion of the non-first color light-filtering portion 412 covering the first color light-filtering portion 411, away from the substrate 10 is flush, and then the surface, of the light-shielding layer 50 formed on the surface of the non-first color light-filtering portion 412 away from the substrate 10, facing the substrate is substantially flush, which may avoid the problems of the breakage of the light-shielding layer 50 and separation of the light-shielding layer 50 from the non-first color light-filtering portion 412. In addition, the light-shielding layer 50 is entirely located on the side of the color light-filtering layer 40 away from the substrate 10, which may further improve the dark state effect of the display substrate in the non-display state.

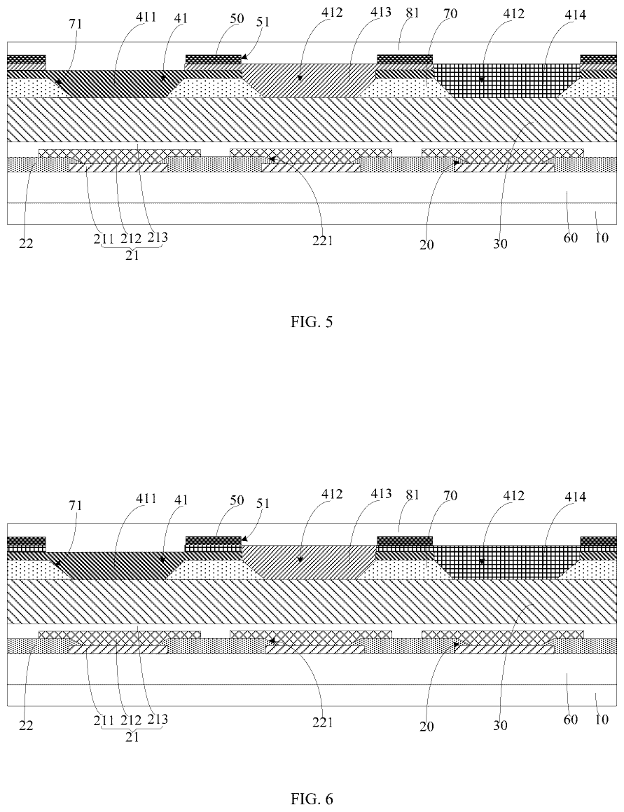

Further, as shown in FIG. 4, for a portion, of the first color light-filtering portion 411, on the side of the defining layer 70 away from the substrate 10, a part of the portion is covered by the second color light-filtering portion(s) 413, and the other part of the portion is covered by the third color light-filtering portion(s) 414; or, as shown in FIG. 5, the portion, of the first color light-filtering portion 411, on the side of the defining layer 70 away from the substrate 10 is entirely covered by the second color light-filtering portion(s) 413; or, as shown in FIG. 6, the portion, of the first color light-filtering portion 411, on the side of the defining layer 70 away from the substrate 10 is entirely covered by the third color light-filtering portion(s) 414.

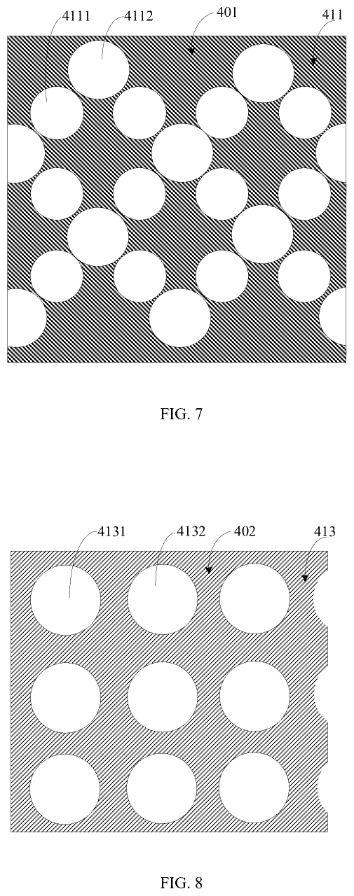

Further, as shown in FIG. 7, the first color light-filtering portions 411 are connected as an integrated structure. The first color light-filtering layer 401 formed by connecting each of the first color light-filtering portions 411 is provided with a plurality of first through-holes 4111 and a plurality of second through-holes 4112. An orthogonal projection of each of the first through-holes 4111 on the substrate 10 covers an orthogonal projection of an opening 71 in which one second color light-filtering portion 413 is located on the substrate 10. An orthogonal projection of each of the second through-holes 4112 on the substrate 10 covers an orthogonal projection of an opening 71 in which one third color light-filtering portion 414 is located on the substrate 10.

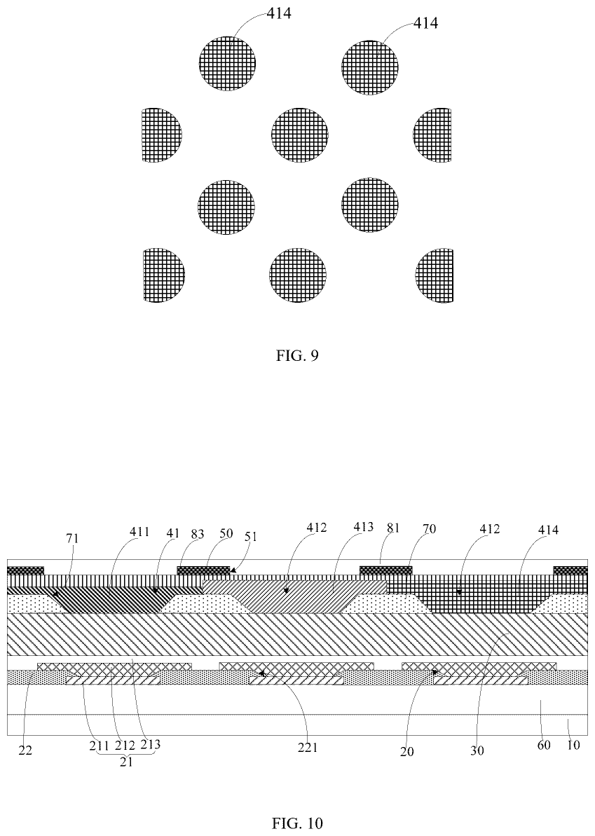

Further, as shown in FIG. 8, the respective second colour light-filtering portions 413 are connected as an integrated structure. The second color light-filtering layer 402 formed by connecting the second color light-filtering portions 413 is provided with a plurality of third through-holes 4131 and a plurality of fourth through-holes 4132. An orthogonal projection of each of the third through-holes 4131 on the substrate 10 covers an orthogonal projection of an opening 71 in which one first color light-filtering portion 411 is located on the substrate 10. An orthogonal projection of each of the fourth through-holes 4132 on the substrate 10 covers an orthogonal projection of an opening 71 in which one third color light-filtering portion 414 is located on the substrate 10. As shown in FIG. 9, the third color light-filtering portions 414 are spaced apart from each other. In other embodiments, the second color light-filtering portions 413 are spaced apart from each other, and the third color light-filtering portions 414 are connected as an integrated structure. The third color light-filtering layer formed by connecting the third color light-filtering portions 414 may be provided with a plurality of fifth through-holes and a plurality of sixth through-holes. An orthogonal projection of each of the fifth through-holes on the substrate covers an orthogonal projection of one first color light-filtering portion 411 on the substrate. An orthogonal projection of each of the sixth through-holes on the substrate covers an orthogonal projection of one second color light-filtering portion 413 on the substrate.

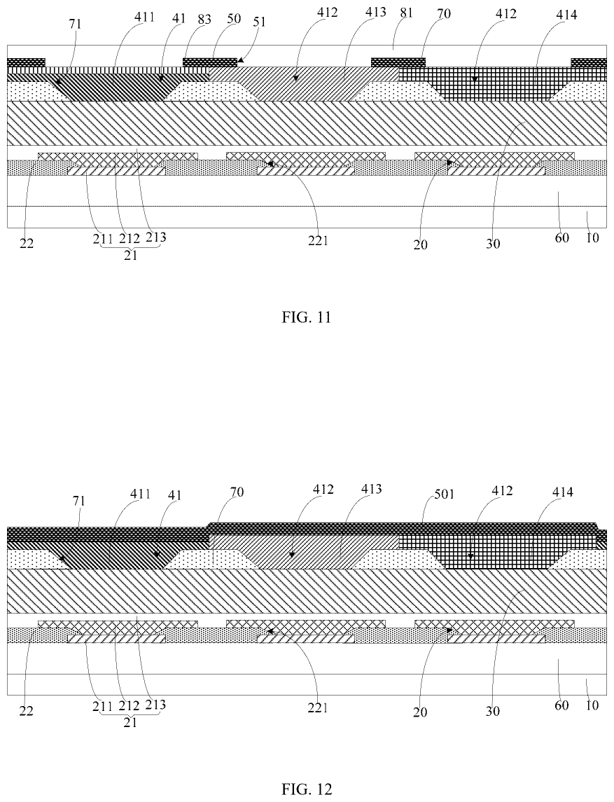

In an embodiment, as shown in FIG. 10 and FIG. 11, the display substrate further includes a planarization layer 83 between the light-shielding layer 50 and the color light-filtering layer 40, and the planarization layer 83 at least covers the first color light-filtering portion 411. By setting the planarization layer 83 at least covering the first color light-filtering portion 411, a height difference between the first color light-filtering portion 411 and the non-first color light-filtering portion 412 may be flattened, thereby avoiding the problems of the breakage of the light-shielding layer 50 and the separation of the light-shielding layer 50 from the adjacent film layer caused by the height difference between the first color light-filtering portion 411 and the non-first color light-filtering portion 412.

In an embodiment, as shown in FIG. 10, an orthogonal projection of the planarization layer 83 on the substrate covers an orthogonal projection of the color light-filtering layer 40 on the substrate, and the surface of the light-shielding layer 50 facing the substrate 10 is entirely in contact with the planarization layer 83. That is, the planarization layer 83 covers a surface of the first color light-filtering portion 411 away from the substrate 10 and a surface of the non-first color light-filtering portion 412 away from the substrate 10. The surface of the planarization layer 83 away from the substrate 10 is flush everywhere. In this embodiment, the manufacturing of the planarization layer 83 is relatively simple.

In another embodiment, as shown in FIG. 11, the planarization layer 83 covers the first color light-filtering portion 411, the surface of the planarization layer 83 away from the substrate 10 is flush with the surface of the non-first color light-filtering portion 412 away from the substrate 10, and a part of the surface of the light-shielding layer 50 facing the substrate 10 is in contact with the planarization layer 83 and the other part of the surface is in contact with the non-first color light-filtering portion 412. By this setting, the distance between the light-shielding layer 50 and the color light-filtering portion 41 may be reduced, which helps to reduce the amount of the light emitted by the light-emitting structure 21 absorbed by the light-shielding layer 50 and improve the light exiting efficiency. In addition, the light-shielding layer 50 is entirely located on the side of the color light-filtering layer 40 away from the substrate 10, which may further improve the dark state effect of the display substrate in the non-display state.

In an embodiment, the material of the planarization layer 83 may be the same as the material of the protection layer 81. This helps to improve a bonding force between the planarization layer 83 and the protection layer 81. In other embodiments, the material of the planarization layer 83 may be different from the material of the protection layer 81.

An embodiment of the present disclosure further provides a method for manufacturing a display substrate. The method for manufacturing a display substrate includes the following steps.

Firstly, a substrate is provided.

In an embodiment, the substrate may be a flexible substrate or a rigid substrate. The material of the flexible substrate may include one or more of polyethylene terephthalate, polycarbonate, and an organic resin material. The organic resin material may include epoxy resin, triazine, silicone resin, polyimide, etc. The rigid substrate includes any one of for example a glass substrate, a quartz substrate, a sapphire substrate, etc.

Subsequently, the light-emitting layer is formed on the substrate, and the light-emitting layer includes a plurality of light-emitting structures spaced apart from each other.

In an embodiment, before forming the light-emitting layer on the substrate, the method for manufacturing a display substrate further includes: forming a driving circuit layer on the substrate, where the driving circuit layer includes a plurality of pixel circuits.

In an embodiment, the light-emitting layer includes light-emitting structures emitting at least three different colors of light. For example, the light-emitting layer may include a light-emitting structure emitting red light, a light-emitting structure emitting green light, and a light-emitting structure emitting blue light. The light-emitting structure may be an OLED.

Subsequently, an encapsulation layer is formed on a side of the light-emitting layer away from the substrate.

In an embodiment, the encapsulation layer is a thin film encapsulation layer, the thin film encapsulation layer includes one or more organic layers and one or more inorganic layers alternately arranged, and a film layer with a maximum distance from the substrate is an inorganic layer.

Subsequently, a color light-filtering layer is formed on a side of the encapsulation layer away from the substrate. The color light-filtering layer includes a plurality of color light-filtering portions; the color light-filtering portions include one or more first color light-filtering portions and one or more non-first color light-filtering portions with color different from a color of each of the first color light-filtering portions; a thickness of each of the first color light-filtering portions is less than a thickness of each of the non-first color light-filtering portions; and a distance from a surface of each of the first color light-filtering portions away from the substrate to the substrate is less than a distance from a surface of each of the non-first color light-filtering portions away from the substrate to the substrate.

In an embodiment, before forming the color light-filtering layer on the side of the encapsulation layer away from the substrate, the method for manufacturing a display substrate further includes: forming a defining layer on the side of the encapsulation layer away from the substrate, where the defining layer is provided with a plurality of openings, and the defining layer is for defining each of the color light-filtering portions.

In an embodiment, the color light-filtering portion is at least partially located in the opening. The color light-filtering portions may correspond to the openings one-to-one, and each of the color light-filtering portions is at least partially located in a corresponding opening.

Subsequently, a light-shielding film layer is formed on a side of the color light-filtering layer away from the substrate. An orthogonal projection of the light-shielding film layer on the substrate covers the substrate, and a thickness of the light-shielding film layer is greater than a height difference between the surface of each of the non-first color light-filtering portions away from the substrate and the surface of each of the first color light-filtering portions away from the substrate.

A first intermediate structure shown in FIG. 12 may be obtained by the above steps. As shown in FIG. 12, the thickness of the light-shielding film layer 501 is greater than the height difference between the surface of the non-first color light-filtering portion 412 away from the substrate 10 and the surface of the first color light-filtering portion 411 away from the substrate 10. By this setting, when the light-shielding film layer 501 is formed, the light-shielding film layer 501 may flat the difference-in-level between the first color light-filtering portion 411 and the non-first color light-filtering portion 412, which may thereby avoid the problems of the breakage of the light-shielding film layer 501 at the boundary between the non-first color light-filtering portion 412 and the first color light-filtering portion 411 and the separation of the light-shielding layer 50 from the color light-filtering layer.

Subsequently, a light-shielding layer is obtained by patterning the light-shielding film layer to form a plurality of holes. An orthogonal projection of one of the holes on the substrate is within an orthogonal projection of one of the color light-filtering portions on the substrate.

In an embodiment, the light-shielding film layer 501 may be patterned by the exposure and development process, and the amount of the light entering different regions of the light-shielding film layer 501 may be controlled by the halftone mask plate during the exposure and development process.

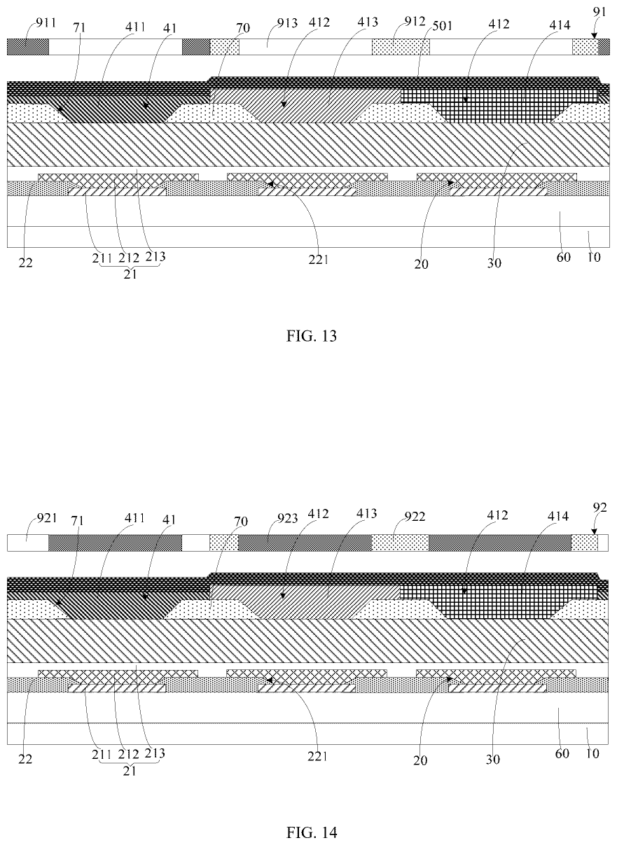

In an embodiment, a second intermediate structure shown in FIG. 13 is obtained, after the halftone mask plate is disposed on a side of the first intermediate structure away from the substrate. As shown in FIG. 13, the used halftone mask plate 91 includes a first mask region 911, a second mask region 912, and a third mask region 913. A light transmittance of the first mask region 911 is less than a light transmittance of the second mask region 912, and the light transmittance of the second mask region 912 is less than a light transmittance of the third mask region 913, where the light transmittance of the first mask region 911 may be 0. The material of the light-shielding film layer 501 is positive photoresist, and the portion of the light-shielding film layer 501 entered by the light passing through the halftone mask plate 91 may be subsequently dissolved and removed by a developing solution. The third mask region 913 is opposite to the opening 71 of the defining layer 70, and the region of the light-shielding film layer 501 opposite to the third mask region 913 is finally entirely removed to form a hole. In the region of the light-shielding film layer 501 opposite to the surface of the defining layer 70 away from the substrate 10, a region in contact with the non-first color light-filtering portion 412 is opposite to the second mask region 912, a region in contact with the first color light-filtering portion 411 is opposite to the first mask region 911, and a thickness of a portion of the finally formed light-shielding layer 50 in contact with the first color light-filtering portion 411 is greater than a thickness of a portion of the finally formed light-shielding layer 50 in contact with the second color light-filtering portion 412. In some embodiments, the light transmittance of the second mask region 912 may be 50%, and the light transmittance of the third mask region 913 may be 25%.

In another embodiment, a third intermediate structure shown in FIG. 14 is obtained, after the halftone mask plate is disposed on a side of the first intermediate structure away from the substrate. As shown in FIG. 14, the used halftone mask plate 92 includes a fourth mask region 921, a fifth mask region 922, and a sixth mask region 923. A light transmittance of the fourth mask region 921 is greater than a light transmittance of the fifth mask region 922, the light transmittance of the fifth mask region 922 is greater than a light transmittance of the sixth mask region 923, where the light transmittance of the sixth mask region 923 is 0. The material of the light-shielding film layer 501 is negative photoresist, the portion of the light-shielding film layer 501 entered by the light passing through the halftone mask plate 92 is not subsequently dissolved by the developing solution, and the portion of the light-shielding film layer 501 not entered by the light may be subsequently dissolved and removed by the developing solution. The sixth mask region 923 is opposite to the opening 71 of the defining layer 70, and the region of the light-shielding film layer 501 opposite to the sixth mask region 923 is finally entirely removed to form a hole. In the region of the light-shielding film layer 501 opposite to the surface of the defining layer 70 away from the substrate 10, a region in contact with the non-first color light-filtering portion 412 is opposite to the fifth mask region 922, a region in contact with the first color light-filtering portion 411 is opposite to the fourth mask region 921, and the thickness of the portion of the finally formed light-shielding layer 50 in contact with the first color light-filtering portion 411 is greater than the thickness of the portion of the finally formed light-shielding layer 50 in contact with the second color light-filtering portion 412. In some embodiments, the light transmittance of the fourth mask region 921 may be 50%, and the light transmittance of the fifth mask region 922 may be 20%.

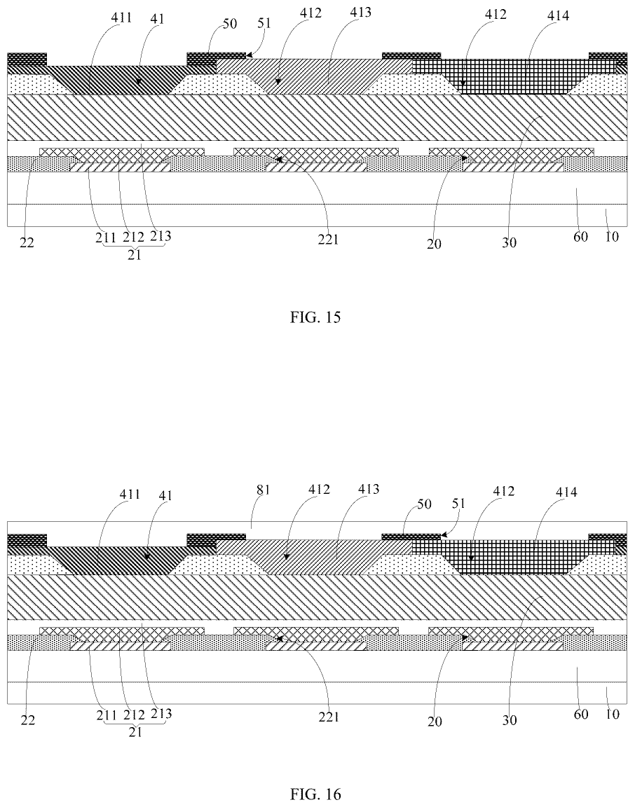

A fourth intermediate structure shown in FIG. 15 is obtained by the step of patterning the light-shielding film layer. As shown in FIG. 15, the surface of the light-shielding layer 50 away from the substrate 10 is flush everywhere.

In an embodiment, a thickness of the light-shielding film layer 501 is greater than a maximum thickness of the light-shielding layer 50. This helps to avoid the breakage of the light-shielding film layer 501.

In an embodiment, after the step of patterning the light-shielding film layer, the method for manufacturing a display substrate further includes the following step of: forming a protection layer. The display substrate shown in FIG. 16 may be obtained by this step. As shown in FIG. 16, the protection layer 81 covers the light-shielding layer 50 and a region of the color light-filtering layer 40 not covered by the light-shielding layer 50.

An embodiment of the present disclosure further provides a display substrate. As shown in FIG. 16, the display substrate includes a substrate 10, and a light-emitting layer 20, an encapsulation layer 30, a color light-filtering layer 40, and a light-shielding layer 50 that are located on the substrate 10.

The light-emitting layer 20 includes a plurality of light-emitting structures 21 spaced apart from each other. The encapsulation layer 30 is located on a side of the light-emitting layer 20 away from the substrate 10. The color light-filtering layer 40 is located on a side of the encapsulation layer 30 away from the substrate 10, the color light-filtering layer 40 includes a plurality of color light-filtering portions 41, the color light-filtering portions 41 include one or more first color light-filtering portions 411 and one or more non-first color light-filtering portions 412 with color different from a color of each of the first color light-filtering portions 411, and a thickness of each of the first color light-filtering portions 411 is less than a thickness of each of the non-first color light-filtering portions 412. The light-shielding layer 50 is provided with a plurality of holes 51, and an orthogonal projection of one of the holes 51 on the substrate is within an orthogonal projection of one of the color light-filtering portions 41 on the substrate 10. The light-shielding layer 50 is located on a side of the color light-filtering layer 40 away from the substrate 10, and a surface of the light-shielding layer 50 away from the substrate 10 is substantially flush. The light-shielding layer 50 is in direct contact with a surface of the first color light-filtering portion 411 away from the substrate 10 and a surface of the non-first color light-filtering portion 412 away from the substrate 10, respectively.

The embodiment of the display substrate provided by the embodiment of the present disclosure and the embodiment of the method for manufacturing a display substrate described above belong to the same inventive concept, and description of related details and beneficial effects may be referred to each other, which will be not repeated herein.

An embodiment of the present disclosure further provides a display apparatus. The display apparatus includes the display substrate of any one of the above embodiments.

In an embodiment, the display apparatus further includes a driver and a power circuit. The driver is for providing a driving signal driving the light-emitting structure to emit light, and the power circuit is for supplying power to the display substrate.

In an embodiment, the display apparatus further includes a housing, and the display substrate is disposed within the housing.

The display apparatus provided by the embodiment of the present disclosure may be, for example, any device having a display function, such as a mobile phone, a tablet computer, a television, a notebook computer, a vehicle-mounted device, etc.

It should be noted that dimensions of layers and regions may be exaggerated for clarity of illustration in the accompanying drawings. In addition, it can be understood that when an element or layer is referred to as being “on” another element or layer, the element or layer may be directly on the another element or layer, or there may be an intervening layer. In addition, it can be understood that when an element or layer is referred to as being “under” another element or layer, the element or layer may be directly under the another element or layer, or there may be more than one intervening layer or element. In addition, it can also be understood that when a layer or element is referred to as being “between” two layers or elements, the element or layer may be an only layer between the two layers or elements, or there may also be more than one intervening layer or element. Similar reference signs indicate similar elements throughout.

Those skilled in the art will easily come up with other implementation solutions of the present disclosure after considering the specification and practicing the content disclosed herein. The present disclosure aims to cover any variation, use, or adaptive change of the present disclosure, which follows general principles of the present disclosure and include common knowledge or customary technical means in the art not disclosed in the present disclosure. The specification and embodiments are only considered exemplary, and the true scope and spirit of the present disclosure are indicated by the following claims.

It should be understood that the present disclosure is not limited to the precise structure described above and shown in the drawings, and various modifications and changes may be made without departing from its scope. The scope of the present disclosure is limited only by the appended claims.

1. A display substrate, comprising:
a substrate;
a light-emitting layer on the substrate; wherein the light-emitting layer comprises a plurality of light-emitting structures spaced apart from each other;
an encapsulation layer on a side of the light-emitting layer away from the substrate;
a color light-filtering layer on a side of the encapsulation layer away from the substrate; wherein the color light-filtering layer comprises a plurality of color light-filtering portions, the color light-filtering portions comprise one or more first color light-filtering portions and one or more non-first color light-filtering portions with color different from a color of each of the first color light-filtering portions, and a thickness of each of the first color light-filtering portions is less than a thickness of each of the non-first color light-filtering portions; and
a light-shielding layer with holes, wherein an orthogonal projection of one of the holes on the substrate is within an orthogonal projection of one of the color light-filtering portions on the substrate; wherein the light-shielding layer is located on a side of the first color light-filtering portions away from the substrate, and a surface of the light-shielding layer facing the substrate is planar.

2. The display substrate of claim 1, further comprising a defining layer on the side of the encapsulation layer away from the substrate;
wherein the defining layer comprises openings;
each of the color light-filtering portions is at least partially located in one of the openings;
for each of the first color light-filtering portions, the first color light-filtering portion is entirely located within a corresponding opening among the openings, and a surface of the first color light-filtering portion away from the substrate is flush with a surface of the defining layer away from the substrate;
a part of the surface of the light-shielding layer facing the substrate is in contact with the first color light-filtering portions, and another part of the surface of the light-shielding layer facing the substrate is in contact with the defining layer; and
for each of the non-first color light-filtering portions, a part of the non-first color light-filtering portion is on a side of the light-shielding layer away from the substrate.

3. The display substrate of claim 2, wherein, each opening among the openings comprises:
a first opening portion; and
a second opening portion on a side of the first opening portion away from the substrate;
wherein the second opening portion comprises a bottom surface outside the first opening portion and connected to a side surface of the first opening portion, and a side surface extending from an outer edge of the bottom surface in a direction away from the substrate.

4. The display substrate of claim 1, further comprising:
a defining layer on the side of the encapsulation layer away from the substrate; wherein the defining layer comprises openings; wherein each color light-filtering portion among the color light-filtering portions is at least partially located in one of the openings; and
a plurality of padding portions between the first color light-filtering portions and the encapsulation layer,
wherein an orthogonal projection of each opening among the openings on the substrate is within an orthogonal projection of one of the padding portions on the substrate;
wherein a surface of each of the first color light-filtering portions away from the substrate is flush with a surface of each of the non-first color light-filtering portions away from the substrate;
wherein the surface of the light-shielding layer facing the substrate is entirely in contact with the color light-filtering layer.

5. The display substrate of claim 4, wherein a refractive index of each of the padding portions is less than or equal to a refractive index of the color light-filtering layer.

6. The display substrate of claim 4, wherein the padding portions and the defining layer are monolithic.

7. The display substrate of claim 4, wherein the padding portions and the defining layer are separate structures.

8. The display substrate of claim 7, wherein an orthogonal projection of each of the padding portions on the substrate is within an orthogonal projection of one of the first color light-filtering portions on the substrate.

9. The display substrate of claim 8, wherein an edge of the orthogonal projection of each of the padding portions on the substrate is flush with an edge of the orthogonal projection of one of the first color light-filtering portions on the substrate.

10. The display substrate of claim 1, further comprising a defining layer on the side of the encapsulation layer away from the substrate;
wherein the defining layer comprises openings;
wherein each of the color light-filtering portions is at least partially located in one of the openings;
wherein a surface of the defining layer away from the substrate is entirely covered by the first color light-filtering portions;
wherein for each of the first color light-filtering portions, a portion of the first color light-filtering portion on a side of the defining layer away from the substrate is covered by the non-first color light-filtering portions; and
wherein the surface of the light-shielding layer facing the substrate is entirely in contact with the non-first color light-filtering portions.

11. The display substrate of claim 10, wherein the non-first color light-filtering portions comprises one or more second color light-filtering portions and one or more third color light-filtering portions;
wherein, for each of the first color light-filtering portions,
a portion of the first color light-filtering portion on the side of the defining layer away from the substrate is entirely covered by the second color light-filtering portions; or,
the portion of the first color light-filtering portion on the side of the defining layer away from the substrate is entirely covered by the third color light-filtering portions; or,
for the portion of the first color light-filtering portion on the side of the defining layer away from the substrate, a part of the portion is covered by the second color light-filtering portions, and other part of the portion is covered by the third color light-filtering portions.

12. The display substrate of claim 11, wherein the second color light-filtering portions are monolithic, or the third color light-filtering portions are monolithic.

13. The display substrate of claim 10, wherein the first color light-filtering portions are monolithic.

14. The display substrate of claim 2, wherein a refractive index of each of the color light-filtering portions is larger than a refractive index of the defining layer.

15. The display substrate of claim 1, further comprising a planarization layer between the light-shielding layer and the color light-filtering layer; wherein the planarization layer at least covers the first color light-filtering portions.

16. The display substrate of claim 15, wherein an orthogonal projection of the planarization layer on the substrate covers an orthogonal projection of the color light-filtering layer on the substrate, and the surface of the light-shielding layer facing the substrate is entirely in contact with the planarization layer.

17. The display substrate of claim 15, wherein a surface of the planarization layer away from the substrate is flush with a surface of each of the non-first color light-filtering portions away from the substrate, and
a part of the surface of the light-shielding layer facing the substrate is in contact with the planarization layer, and another part of the surface is in contact with the non-first color light-filtering portions.

18. A method for manufacturing a display substrate, comprising:
providing a substrate;
forming a light-emitting layer on the substrate; wherein the light-emitting layer comprises a plurality of light-emitting structures spaced apart from each other;
forming an encapsulation layer on a side of the light-emitting layer away from the substrate;
forming a color light-filtering layer on a side of the encapsulation layer away from the substrate; wherein the color light-filtering layer comprises a plurality of color light-filtering portions; the color light-filtering portions comprise one or more first color light-filtering portions and one or more non-first color light-filtering portions with color different from a color of each of the first color light-filtering portions; a thickness of each of the first color light-filtering portions is less than a thickness of each of the non-first color light-filtering portions; and a distance from a surface of each of the first color light-filtering portions away from the substrate to the substrate is less than a distance from a surface of each of the non-first color light-filtering portions away from the substrate to the substrate;
forming a light-shielding film layer on a side of the color light-filtering layer away from the substrate; wherein an orthogonal projection of the light-shielding film layer on the substrate covers the substrate, and a thickness of the light-shielding film layer is greater than a height difference between the surface of each of the non-first color light-filtering portions away from the substrate and the surface of each of the first color light-filtering portions away from the substrate; and
obtaining a light-shielding layer by patterning the light-shielding film layer to form a plurality of holes; wherein an orthogonal projection of one of the holes on the substrate is within an orthogonal projection of one of the color light-filtering portions on the substrate.

19. The method for manufacturing a display substrate of claim 18, wherein the thickness of the light-shielding film layer is greater than a maximum thickness of the light-shielding layer.

20. A display apparatus, comprising the display substrate of claim 1.
